(19) United States
(12) Patent Application Publication
(10) Pub. No.: US 2002/0145475 A1
(43) Pub. Date: Oct. 10, 2002

(54) Dual conversion RF synthesizer utilizing improved push-push VCO design

(75) Inventors: Eliot Fenton, Pembroke Pines, FL (US); Claudio Cassina, Hollywood, FL (US); Zhong Han, Delray Beach, FL (US); Joseph Paniccia, Boca Raton, FL (US)

Correspondence Address: Dale Paul DiMaggio, Esq., Malin, Haley & DiMaggio, P.A., 1936 South Andrews Avenue, Fort Lauderdale, FL, 33316, US

(73) Assignee: APA Wireless Technologies

(21) Appl. No.: 09/829,609

(22) Filed: Apr. 10, 2001

(51) Int. Cl. H03B 5/18; H03L 7/18; H03L 7/197

(52) U.S. Cl. 331/25; 331/31; 331/100; 331/114; 331/117 D; 331/177 V

(57) ABSTRACT

A dual conversion, noise resistant, digitally-controlled mm-wave frequency synthesizer for generating rapidly-tunable RF signals. The prime signal-generation source is a 3.0-3.2 GHz low noise wide band voltage controlled oscillator (“vco”). The oscillator includes a buried stripline hairpin resonator having dual-tuning circuits to increase bandwidth coverage and unique bias circuitry to improve phase noise. The oscillator frequency is multiplied by a factor of two, yielding a 6.0-6.4 GHz signal that is mixed with a fixed locally generated carrier of 3900 MHz, the output of which represents the first Intermediate Frequency (IF). This IF is then mixed with 1950 MHz (3900 MHz divided by two), yielding a second IF that covers the 188 to 550 MHz range. The 2^{nd} IF is divided down and phase locked to an external reference using a commercially available chip set. The 6.0-6.4 phase locked signal is then re-mixed with the 3.0-3.2 GHz output form the oscillator, thereby yielding a 9.0-9.6 GHz signal. The 9.0-9.6 signal is then multiplied by two to yield a 18.0-19.2 GHz signal. This signal is amplified by a mm-wave amplifier, which also contains a detector diode for output power monitoring. The voltage from the detector diode is fed back to an on-board microcontroller which maintains the RF output power within an acceptable range. By using harmonically related signals for the mix approach, no mixer spurious signals are generated.

### BACKGROUND OF THE INVENTION

1. Field of the Invention

This invention relates generally to wireless communication systems, and more particularly, to a noise resistant, digitally-controlled mm-wave frequency synthesizer module for generating RF signals with the capability of changing frequencies up to 1,000 times faster than conventional YIG-based synthesizers.

2. Description of the Prior Art

In the world of wireless communication, RF modules are used to generate and control the microwave frequencies used for data transmission. The RF modules compress information into packets, translate them into radio frequencies and transmit them between fixed wireless stations. The goal is to pack greater amounts of data into existing frequencies at a low cost.

Microwave and millimeter wave frequency synthesizers must be highly resistant to vibration and need to generate fast, accurate and reliable waveforms capable of changing frequencies rapidly. It is desirable to be able to obtain a broad range of frequency coverage and to rapidly tune and control these frequencies.

Currently, in the field of low power microwave frequency generation, there are two common types of oscillator frequency control that are adaptable to either open or closed loop architectures. These oscillator types are the yttrium-iron-garnet (YIG) tuned oscillators and voltage tuned oscillators (VTO). Phase locked loops (PLLs) utilize either of these oscillators in a closed loop architecture as a common means for achieving precise frequency control.

For years, the YIG (yttrium iron garnet) oscillators have been utilized as a broadband, high frequency source in wireless radio transmission systems. A YIG oscillator is based on a rare earth material that generates clean microwave signals. YIGs are RF carrier generation devices that are characterized by good phase noise, even when covering octave bandwidths at mm-wave frequencies. Microwave and millimeter wave products incorporating YIG technology are used primarily in wireless telecommunication, test and measurement, and defense electronic markets. YIG technology is also used in such applications as free-running and phase locked oscillators in narrow and wide band configurations, band-pass and band-reject filters, narrow and wide band frequency synthesizers and converters as well as highly integrated front-end, modules for digital radio applications.

Typical prior art synthesizers, are of the type described in U.S. Pat. No. 5,508,661 (“the '661 patent”) and U.S. Pat. No. 5,770,977 (“the '977 patent”), the disclosures of each which are incorporated herein by reference. The '661 patent describes a YIG frequency synthesizer having a direct digital synthesizer (DDS) with a tuning speed of approximately 100 nanoseconds. A 500 MHz Surface Acoustic Wave (SAW) oscillator generates a sine wave which drives a step recovery diode to generate a spectrum of harmonics. One of these harmonics is selected by a switched array of fixed-tuned YIG band pass filters, each of which is tuned to pass one harmonic only. The selected harmonic is used to translate the frequency of the output of a Direct Digital Synthesizer (DDS) operating between 250 MHz and 500 MHz. By modulating the DDS output frequency with a selected comb line form the SAW, output frequencies in the 5 to 10 GHz range is attained, with low phase noise. The nanosecond tuning capability allows for a rapid sweep in frequency across a wide range of frequencies.

YIG-tuned oscillators can tune over wide ranges of microwave frequencies, often over multiple frequency octaves. Yet, YIG oscillators are limited in their tuning speed and settling time by the physics of the magnetics which establishes the flux that changes the resonant frequency of the YIG sphere which is the integral resonator of the YIG oscillator circuit. Tuning is performed by passing a control current through a main tuning coil that directly affects the magnetic flux. However, the time response of the magnetic circuit causes the slow tuning and frequency settling characteristics associated with YIG circuits. These times are on the order of one to several milliseconds, depending upon the size of the commanded frequency change and required stability of the settled frequency. Most YIG oscillators also incorporate a smaller FM coil which directly interacts with the YIG sphere for rapid tuning over a small range, typically 100 MHz. This coil is often used to sweep the frequency of the YIG-tuned oscillator.

The magnetic tuning structure of both of these coils also exhibits a hysteresis characteristic, common to magnetics, which causes the oscillator to exhibit an apparent change in frequency as the device is first tuned upward and then downward. This contributes to uncertainty in the commanded frequency.

The current/frequency transfer characteristic for both the main and FM tuning coils is linear with a constant rate of change. However, the YIG resonators are very temperature dependent, requiring an oven structure to elevate their internal temperatures to maintain frequency stability. Overall, this class of oscillators exhibits frequency uncertainties due to temperature, hysteresis and non-linearity of greater than 30 to 40 MHz when operated with temperature control in an open loop architecture. Resolution of frequency set-on depends upon the ability to control the current supplied to the tuning coils. This is often accomplished by converting digital control commands into requisite control currents for the tuning coils with frequency compensations often effected by digital corrections ahead of this conversion process. In a closed loop configuration, a YIG oscillator can be stabilized to a reference oscillator with the YIG oscillator frequency very accurately known and stability comparable to its reference. This is obtained at the expense of significantly slower frequency settling characteristics.

Another class of electrically tunable oscillators is broadly known as Voltage Controlled Oscillators (VCOs) or Voltage Tunable Oscillators (VTOs). VCOs are essentially the building blocks of telecommunication systems. Modern transceivers need fully integrated VCOs that meet stringent phase noise specifications using minimal power. The soaring market for wireless communications has pushed for higher operating frequencies in order to meet consumer demands for large bandwidth applications. Wide bandwidth frequency control of this type of oscillator required the application of abrupt or hyperabrupt varactor diodes as their voltage dependent tuning element. Abrupt varactor-tuned oscillators are tunable over a frequency range of one octave or less with a significantly non-linear control voltage characteristic, often requiring large control voltages.

Alternatively, hyperabrupt varactor-tuned oscillators exhibit a relatively linear voltage tuning characteristic over about 45% of a frequency octave using modest control voltages. The settling time for either type of device is under a microsecond. Frequency resolution depends upon the ability to control the voltage used to tune the varactor diode. This is often accomplished by digital quantization of the control voltage with requisite compensations and corrections performed digitally.

In a closed loop configuration, the VTO can be stabilized to a reference oscillator frequency at the penalty of slower frequency settling characteristics. A further consideration is that the modulation sensitivity (MHz/volt) of the VTO which changes moderately over the controllable frequency range of the VTO, being less sensitive at higher frequencies. This may require the provisions for a second control circuit to maintain independent compensation to assure a constant modulation characteristic.

If high frequency set-on accuracy and stability are required, then a PLL architecture using YIGs or VTOs as microwave sources is commonly in a closed loop configuration. However, the settling time of a PLL is determined by the time response characteristic of the control loop which, at best, is about one hundred times the inverse of the frequency resolution increment. Thus, as the frequency resolution increments decrease, the settling time increases very rapidly. Once locked, however, a PLL retains the temperature stability of its frequency reference oscillator and does not require additional analog or digital compensation.

While YTOs and VTOs are self-resonant at microwave frequencies, the application of PLLs at these frequencies requires a coherent microwave frequency reference to downconvert the output frequency of the controlled oscillator (YTO or VTO) to frequencies (digital clock rates) which are compatible with the digital counter components used in the control loop. This reference frequency is usually obtained from a comb generator that is coherent with the reference oscillator. The spurious frequency content of a properly designed phase locked loop is extremely small and approaches that of the reference oscillator.

Other microwave frequency generators, such as the type disclosed in the '997 patent, utilize a variant of the DDS architecture.

Direct digital synthesizers (DDSs) utilize digital signal processing technology embedded into special integrated components to create a single frequency output for each digital input frequency command. A DDS is implemented as a digital phase accumulator, synchronously clocked by a stable oscillator. The DDS output addresses a read only memory (ROM), modulo output frequency. This ROM contains fine grain sine wave data which is converted to an analog output by a digital-to-analog (D/A) converter whose low pass filtered output is an RF carrier at the programmed frequency. This technique is commonly used at frequencies well below 100 MHz for high precision receivers and the like. Due to the sampled digital nature of the DDSs, the frequency output of this class of oscillator exhibits very large spurious content, dependent upon the fractional relationship of the commanded frequency to the input clock rate. Generally, DDSs are limited to command frequencies which are less than 0.4 of the clock frequency. Above this value and particularly at commands approaching one half the clock frequency, the spurious content becomes very large and makes the output unusable. DDS oscillators operating at frequencies above 100 MHz generally can only be commanded to frequencies which are less than one fourth the clock frequency to keep spurious content to minimum values.

However, despite the popularity of YIG and other microwave frequency generators used as a broadband RF source, they all include many inherent problematic characteristics, rendering each impractical in the rapidly-changing wireless communication world. YIG technology requires costly hand assembly, changes frequencies slowly, is sensitive to noise and vibration and has failure rates approaching 40 percent. Further disadvantages are slow tuning speed, high power requirements, lack of control, mechanical component breakdown, susceptibility to wind, rain and electromagnetic interference and the requirement of critical dimensions for construction.

In synthesizer design, various frequencies are combined to produce an IF (Intermediate Frequency), the frequency to which all selected signals are converted for additional amplification, filtering and eventual direction. However, the combining of various frequencies often results in spurious signals. These spurs are unwanted signals produced by an active microwave component, usually at a frequency unrelated to the desired signal or its harmonics.

Accordingly, what is needed in the art is an alternative to the standard YIG wave generation devices, which can generate spurious-free millimeter-wave frequency signals over hundred's of MHz utilizing a dual conversion approach to combine only harmonically-related signals, and which can be controlled by a microcontroller to maintain RF output power within an acceptable range.

It is, therefore, to the effective resolution of the aforementioned problems and shortcomings of the prior art that the present invention is directed.

### SUMMARY OF THE INVENTION

The present invention provides a radio frequency synthesizer module to generate and control microwave frequencies used for high-speed wireless data transmission.

The present invention is an RF carrier signal generation module that uses a multiply and mix down approach to generate mm-wave frequencies. The main signal source for generating these frequencies is a voltage control oscillator (“vco”) known as a YIG Replacement Oscillator, which is a 3.0-3.2 GHz low noise wide band voltage controlled oscillator. The unique design of the oscillator enables the coverage of hundreds of MHz without a phase noise penalty. The oscillator frequency is multiplied by a factor of two, yielding a 6.0-6.4 GHz signal that is mixed with a fixed locally generated carrier of 3900 MHz, the output of which represents the first Intermediate Frequency (IF). This IF is then mixed with 1950 MHz (3900 MHz divided by two), yielding a second IF that covers the 188 to 550 MHz range. The 2^{nd} IF is divided down and phase locked to an external reference using a commercially available chip set.

The 6.0-6.4 phase locked signal is then re-mixed with the 3.0-3.2 GHz output from the vco, thereby yielding a 9.0-9.6 GHz signal. The 9.0-9.6 signal is then multiplied by two to yield a 18.0-19.2 GHz signal. This signal is amplified by a mm-wave amplifier, which also contains a detector diode for output power monitoring. The voltage from the detector diode is fed back to an on-board microcontroller which maintains the RF output power within an acceptable range. By using harmonically related signals for the mix approach, no mixer spurious signals are generated.

In the preferred embodiment of the present invention, the dual conversion frequency synthesizer producing a controlled RF output signal comprises means for generating millimeter wave frequency signals, a frequency doubler for multiplying said millimeter frequency signals by a factor of 2, means for generating a first fixed carrier signal, means for multiplying the fixed carrier signal by a factor of 2, means for coupling the multiplied millimeter frequency signal with the multiplied fixed carrier signal to generate a first IF signal, means for coupling the fixed carrier signal with the first IF signal to produce a second IF signal, an amplifier driving a dual modulus prescaler and fractional PLL chip for phase locking the second IF signal to an external reference, means for coupling the millimeter frequency signal with the phase locked second IF signal to produce a spurious free output signal comprised of harmonically related component signals, second means for multiplying the output signal by a factor of 2 to produce a resultant RF output signal, and means for controlling the power level of the output signal and maintaining the output signal within an acceptable range.

In the preferred embodiment, the means for controlling the power level and maintaining the output signal within an acceptable range comprises a mm-wave amplifier having a detector diode for amplifying and rectifying mm-wave signals and for providing a DC voltage proportional to the power of the resultant RF output signal, and a microcontroller coupled to the mm-wave amplifier, said microcontroller including means for detecting and measuring the value of the DC voltage and further including means for variably adjusting the RF output power.

Preferably, the means for generating a first fixed carrier signal is comprised of an amplifier driven by an external 50 MHz reference signal, a sampling phase detector driven by the amplifier thereby generating harmonic signals of the external reference signal, a voltage controlled oscillator (“VCO”) generating a 1950 MHz signal driving a side of said sampling phase detector and coupling with the harmonic signals thereby producing an output voltage proportional to a phase differential between the 1950 MHz signal and the harmonic signals, phase locking means comprised of an active loop filter controlling the 1950 MHz signal, a microcontroller for determining if the VCO is generating an offset voltage and if so, to provide an opposite swing voltage driving the VCO in an opposite direction, and means for doubling the 1950 MHz signal.

The synthesizer of the present invention is enclosed in a housing comprised of a plurality of pockets for separately enclosing the submodules. Each pocket retains a submodule thereby allowing a submodule to be removed and replaced without the need to alter another submodule. Each submodule communicates with one or more of the other submodules via electrical connectors protruding through the outer side of the bottom of the housing.

The VCO, the main signal source for generating the 3.0-3.2 GHz low noise signal is comprised of a substrate, a stripline hairpin resonator exhibiting a high Q buried within the substrate, an oscillator tuning circuit electrically coupled to the resonator comprised of one or more varactor diodes for tuning the oscillator over a desired frequency range, amplifying means, and a second circuit, comprised of one or more inductors and a second circuit, comprised of one or more inductors in series with the varactor diodes, electrically coupled to the oscillator tuning circuit for tuning the oscillator tuning circuit thereby reducing effective varactor capacitance as frequency increases.

A noise reduction circuit for improving phase noise is included. The circuit comprises an amplifier biasing circuit including an RF choke and means for shunting 1/f noise to ground.

It is therefore an object of the present invention to provide an RF synthesizer module with dual independent outputs and an automatic gain control of each output to keep the carrier level constant over temperature.

It is another object of the present invention to provide an AGC circuit that closely approximates the movement of an analog circuit, yet is controlled digitally.

It is another object of the present invention to provide an RF synthesizer module having low power requirements, low phase noise and fast switching speed.

It is still another object of the present invention to provide an RF synthesizer module utilizing a smart power supply that monitors system parameters.

It is yet another object of the present invention to provide an RF synthesizer module having a unique housing design that minimizes spurious crosstalk.

It is yet another object of the present invention to provide software enabled features to allow remote programming of the RF synthesizer module.

It is yet another object of the present invention to provide an RF synthesizer module using a modular approach that enables rapid changing of system features and capabilities.

It is another object of the present invention to utilize a dual conversion design utilizing only harmonically-related frequencies to eliminate spurious signals.

It is still another object of the present invention to provide a voltage controlled oscillator having a resonator formed via a buried stripline hairpin design to maximize loaded Q and shield the resonator from outside EMI.

It is to be understood that both the foregoing general description and the following detailed description are explanatory and are not restrictive of the invention as claimed. The accompanying drawings, which are incorporated in and constitute part of the specification, illustrate embodiments of the present invention and together with the general description, serve to explain principles of the present invention.

In accordance with these and other objects which will become apparent hereinafter, the instant invention will now be described with particular reference to the accompanying drawings.

### BRIEF DESCRIPTION OF THE DRAWINGS

FIG. 1 is a schematic representation of the Main Loop circuit of the radio frequency synthesizer module of the present invention.

FIG. 2 is a continuation of the schematic representation of the Main Loop circuit of the radio frequency synthesizer module of the present invention.

FIG. 3 is a continuation of the schematic representation of the Main Loop circuit of the radio frequency synthesizer module of the present invention.

FIG. 4 is a continuation of the schematic representation of the Main Loop circuit of the radio frequency synthesizer module of the present invention.

FIG. 5 is a schematic representation of the Sample Loop module of the present invention.

FIG. 6 is a continuation of the schematic representation of the Sample Loop module of the present invention.

FIG. 7 is an assembly drawing of the 9 GHz/18 GHz doubler sub-module of the present invention.

FIG. 8 is a flowchart representing the digital automatic gain control process of the present invention.

FIG. 9 is a continuation of the flowchart of FIG. 8, representing the digital automatic gain control process of the present invention.

FIG. 10 is a schematic representation of the analog integrator circuit of the present invention.

FIG. 11 is an electrical circuit representation of a typical “push-push” voltage control oscillator of the prior art.

FIG. 12 is a schematic representation of the modified voltage control oscillator utilized in the preferred embodiment of the present invention.

FIG. 13 is a top perspective view of the housing which encloses the individual submodules of the present invention.

FIG. 14 is a bottom perspective view of the housing which encloses the individual submodules of the present invention.

FIG. 15 is a cross sectional view of the modified voltage control oscillator utilized in the preferred embodiment of the present invention.

### DESCRIPTION OF THE PREFERRED EMBODIMENTS

The RF synthesizer module of the present invention is comprised of a series of inter-dependent sub-modules, each having distinct functions.

Main Loop

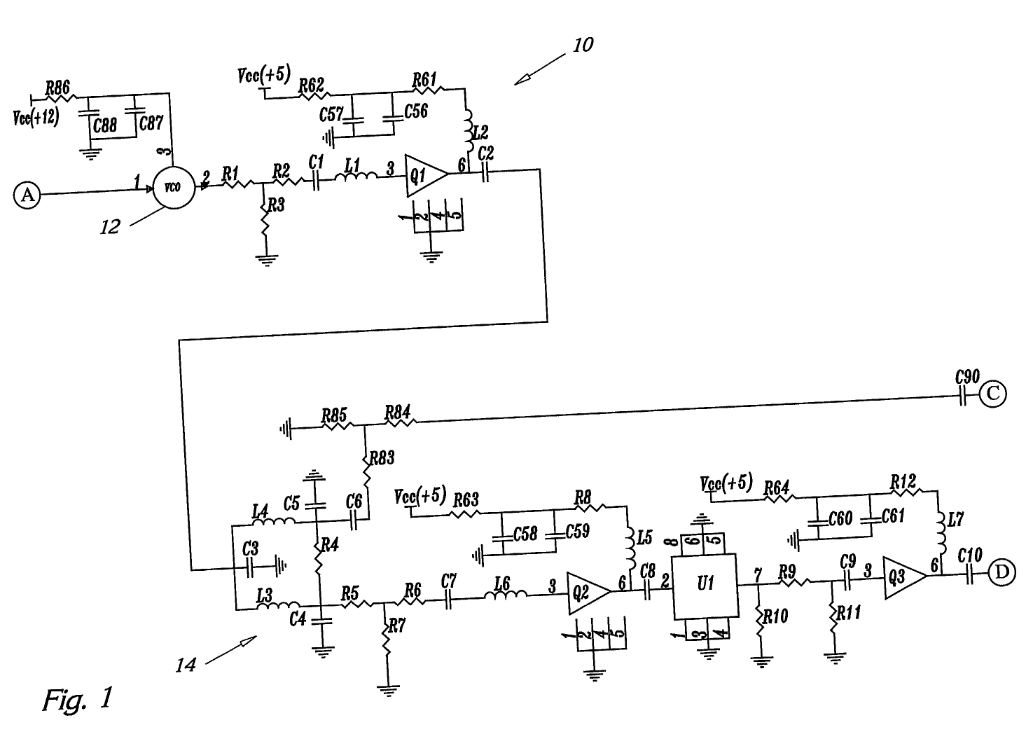

As seen in FIGS. 1-4, the overall Main Loop of the radio frequency synthesizer supermodule of the present invention is illustrated in a circuit diagram and generally designated as 10. Main Loop 10 generally consists of several sub-modules, each controlled by a microcontroller. The microcontroller is preferably a PIC16C73B-201/SP made by Microchip Technology Inc. although it is in the spirit of the invention to use any compatible microcontroller common in the art.

The PIC16C73B is an EPROM-based microcontroller with an integrated Analog-to-Digital Converter. It contains 4096×14 words of program memory, 192 bytes of user RAM and 5 MIPS performance @ 20 MHz. In addition to the 5-channel 8-bit A/D converter, the device includes Brown-Out-Reset (BOR), Power-On-Reset (POR), three timer/counters, two Capture/Compare/PWM modules and two serial ports. The synchronous Serial Port can be configured as either a 3-wire Serial Peripheral Interface (SPI™) or the 2-wire Inter-Integrated Circuit (I2C™) bus. This device also features a Universal Synchronous Asynchronous Receiver Transmitter (USART) which is also known as a Serial Communications Interface (SCI). The PIC16C73B has 22 I/O pins with 25 mA source/sink per I/O.

The purpose of Main Loop module 10 is to generate a 9.0-9.6 GHz signal from a 3.0-3.2 GHz source from a VCO and use a 1950 MHz fixed frequency signal from the Sampling Loop circuit 20 to generate LOs for the first and second IFs. Further, by maintaining all frequencies as harmonically related, spurious content is minimized.

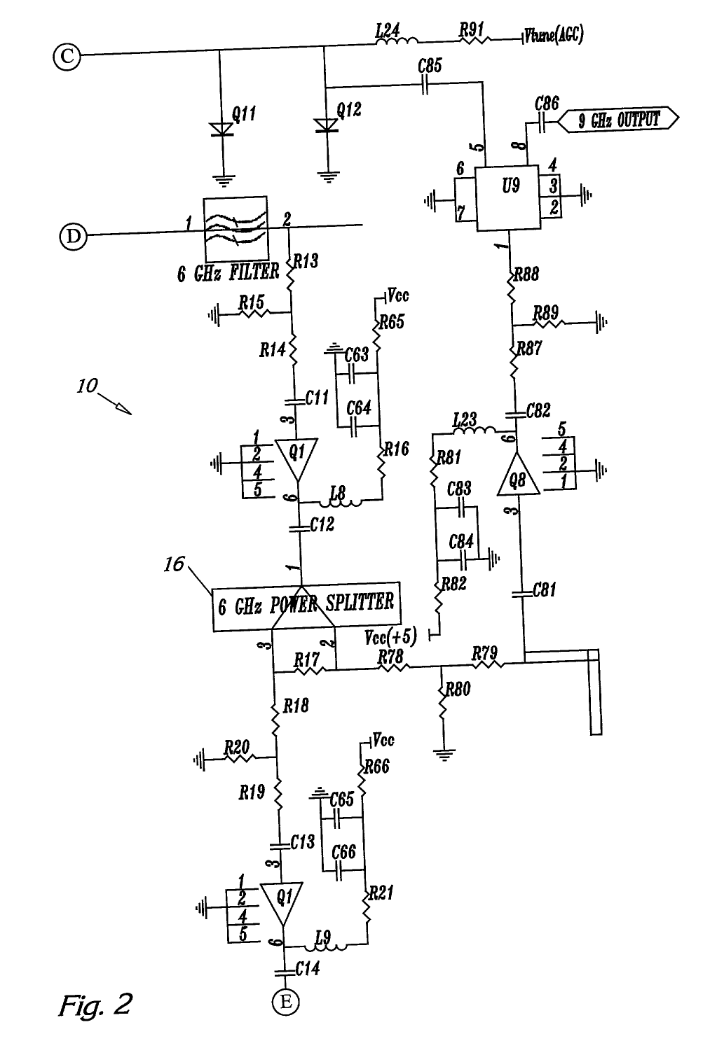

Referring to FIG. 1, in the first portion of Main Loop circuit 10, VCO 12 drives an amplifier Q1 and then a splitter circuit 14. One side of splitter circuit 14 drives a second amplifier Q2 and a frequency doubler U1 yielding a 6.0-6.4 GHz signal. This signal is then mixed with the 3.0-3.2 GHz signal from the other side of the splitter circuit to yield a 9.0-9.6 GHz signal. Mixer U9 performs this operation, as shown in FIG. 2. Since this signal is a combination of harmonically related carriers, there are no mixer spurious generated resulting in a spurious free output signal.

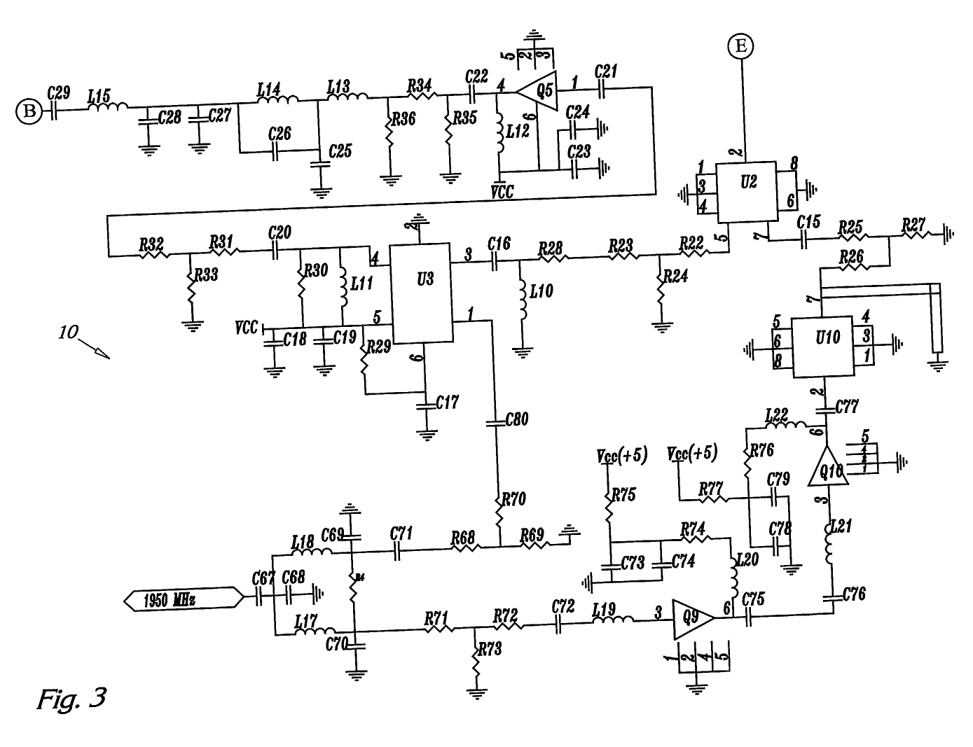

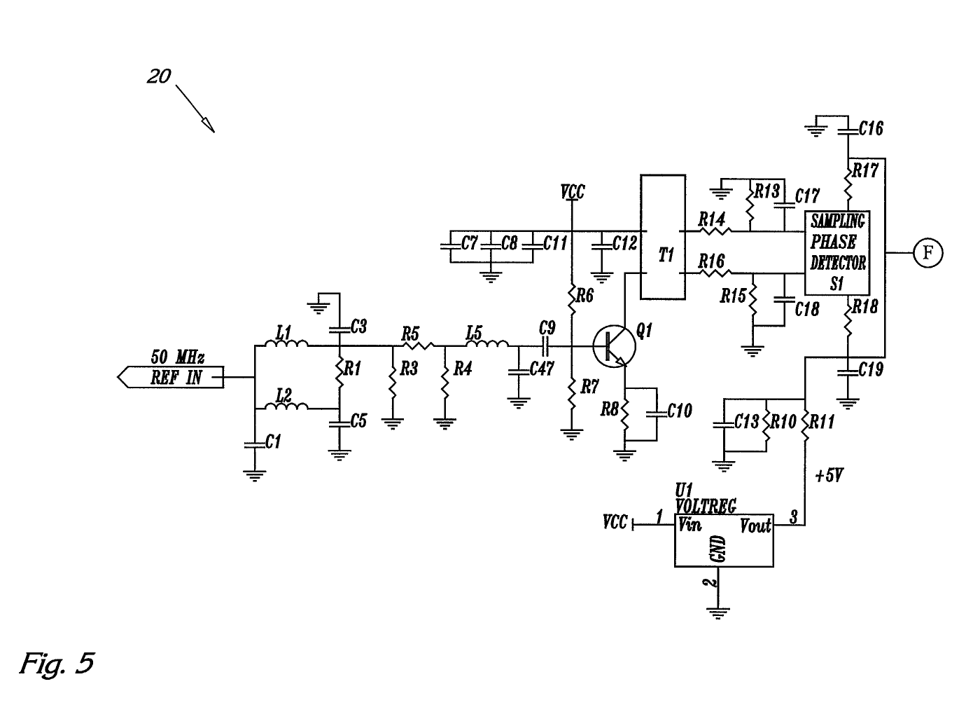

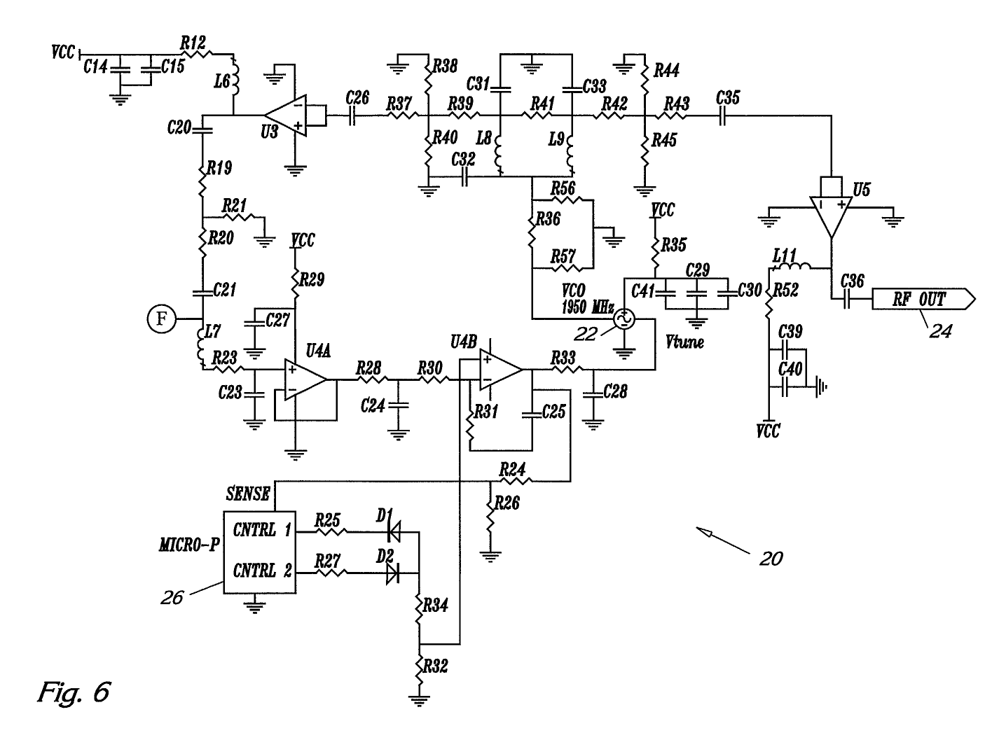

In FIG. 3, in order to phase lock the system, the 6.0-6.4 GHz signal, which also previously drove a series of amplifiers Q1 and a 6 GHz power splitter 16 (shown in FIG. 2), is combined with 3900 MHz, generated from the Sampling Loop 20 (shown in FIGS. 5 and 6), via mixer U2 to create the first Intermediate Frequency (IF). This first IF is then mixed again, via mixer U3, with the 1950 MHz signal, also generated from Sampling Loop 20, to generate the second IF. This second IF then drives an amplifier Q5 for isolation.

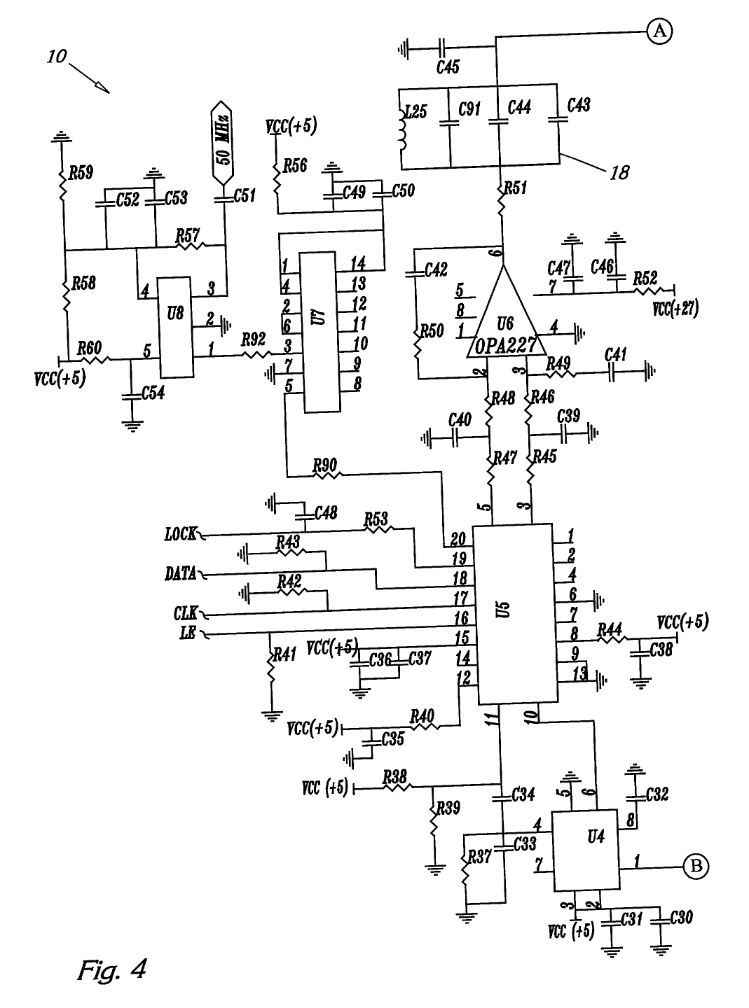

Continuing from the previous figure, in FIG. 4, amplifier Q5 drives a dual modulus prescaler U4 and fractional PLL chip U5. PLL U5, one side driven by a 25 MHz reference signal and the other side driven by the second IF, performs the necessary phase comparison between the two sides, and outputs a voltage corresponding to the phase/frequency difference between the two. This voltage drives an active loop filter 18, whose output drives the VCO's 12 tuning voltage input, which then closes the loop.

An advantage of this type of design is its low division ratio which improves phase noise and loop gain close to the carrier. For example, if the comparison frequency at PLL U5 is 5 MHz, then the highest division ratio for this loop would be 110 ((6400-3900-1950)/5). Since the phase noise and loop gain degrade by a factor of 20*log (division ratio), this approach offers approximately a 20*log (12) improvement in phase noise and loop gain as compared to an approach where the 6400 MHz is divided directly down to 5 MHz (a division ratio of 1280). In addition, if the step size is less than 5 MHz, the PLL will still compare at 5 MHz, but step in fractions thereof (100 KHz, 250 KHz etc.). By using a fractional PLL chip, the synthesizer can increment in smaller step sizes than the comparison frequency, yet retain the low division characteristics.

A further advantage of the dual IF architecture is low spurious. By mixing the 6.0-6.4 GHz signal with the 3900 MHz signal and then the 1950 MHz signal. Spurious signals close to the main 6.0-6.4 GHz carrier are not generated thereby easing the filtering requirements.

The goal behind the Main Loop design is to eliminate or minimize spurious content. The novel theory behind the Main Loop is a dual conversion design which mixes the Sampling Loop frequencies, which are harmonically related. The present invention combines harmonically related signals, to eliminate spurs. The 3900 MHZ (first IF) output and the 1950 MHz output (second IF), are free from spurs. The frequency of the VCO signal is doubled, re-mixed with itself, again a harmonically related signal, and doubled again. Once again, each of these signals are harmonically related. Since each of the combined frequencies are harmonically related, the net result, after mixing, is a spurious-free signal.

Sample Loop

The Sample loop module 20 is shown in FIG. 5. The purpose of this submodule is to generate a low noise and low microphonic 1950 MHz fixed frequency signal to be used for the second intermediate frequency (IF) and is multiplied by a factor N, preferably equal to 2, to 3900 MHz, to be used for the first IF.

Referring now to FIG. 55 the specifics of Sampling Loop module 20 will now be discussed. A 50 MHz signal from an external reference drives a standard 50 MHz amplifier Q1 which drives a transformer T1. The signal from T1 drives a sampling phase detector (SPD) shown as S1. SPD S1 consists of a step recovery diode, coupling capacitors and a shottky diode pair. By driving SPD S1 in a tuned circuit, harmonics of the 50 MHz are generated through 2 GHz.

Referring to FIG. 6, a 1950 MHz VCO 22 drives one side of SPD SI and mixes with a harmonic of the 50 MHz signal, also at 1950 MHz, producing an output voltage 24 proportional to the phase difference between the two. The output generates a mixing frequency, or first IF, which drives an active loop filter having a bandwidth of approximately 150 KHz, which controls VCO 22 and locks the loop. The advantage of this type of loop is that the phase noise is dominated by the reference, and the division ratio is essentially one.

Normally, a sampling loop operates at one frequency, and the goal is to prevent it from locking at the wrong frequencies, to assure locking on the proper frequency, with minimal monitoring. Every time it is monitored, it is disturbed. To prevent false locking on an unintended harmonic of 50 MHz, such as 1900 MHz or 2000 MHz, VCO 22 is designed to generate frequencies only within the 1910 MHz to 1990 MHz range. To assist in acquisition, a novel microcontroller/offset voltage combination, shown as 26, is used to monitor Sampling Loop 20.

When powered up, SPD S1 is intentionally and randomly mis-biased, generating either a minimal positive or minimal negative voltage. This drives the active loop filter to the rail on one side or the other. The fixed offset voltage as applied to SPD S1 will force VCQ 22 either high or low in frequency. Microcontroller 26 senses this offset direction and provides a “swing voltage” to drive the filter and VCO 22 in the opposite direction. When microcontroller 26 forces the active filter to “swing” back towards one of the rails, the acquisition point will be reached and the loop will acquire lock and stability over a wide array of temperature ranges.

9 GHz Amp/Doubler

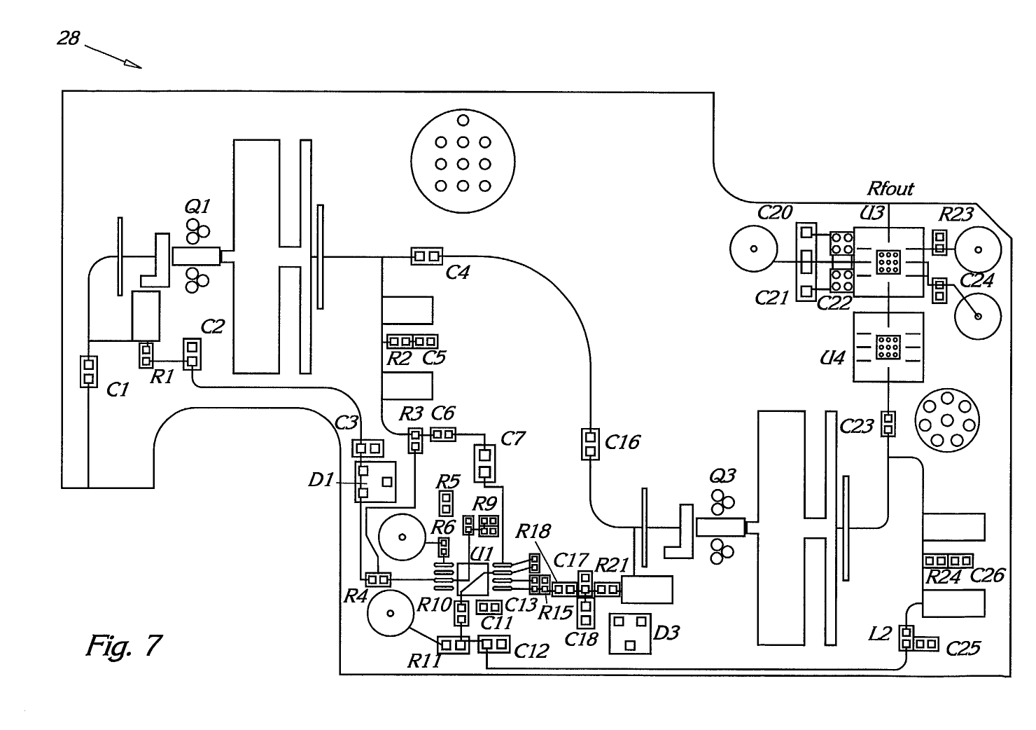

Referring now to FIG. 7, a circuit assembly representation of the 9 GHZ Amp/Doubler module 28 of the present invention is shown. This module takes the 9.0-9.6 GHz signal output from the main loop, passes it through a series of transistors Q1 and Q3 and drives it through doubler U4, amplifier U3 and an edge coupled filter. Mm-wave amplifier U3 provides 20 dB of gain in the 18.0-19.2 GHz range. The amplifier's output drives an edge coupled band pass filter centered in this band, and the output of the filter exits the module via an SMA style connector. Op-amp U1 is used as an active bias controller for transistors Q1 and Q3.

Millimeter-wave amplifier U3 also contains an agc control port. A detector diode rectifies the mm wave signals and provides a DC voltage proportional to the RF carrier output power. This voltage is fed back to the microcontroller, which measures the voltage and adjusts the RF power via a PIN diode attenuator located on the main board.

A unique feature of the agc circuit of the present invention is that it approximates an analog circuit, yet is implemented digitally. The microcontroller, after reading the detected diode voltage, sends a series of narrow pulses to slowly charge a capacitor whose output voltage adjusts to the voltage on the PIN diode. By varying the rate of the pulses, the change in output power can be incremented in very small steps, essentially mimicking an analog control circuit.

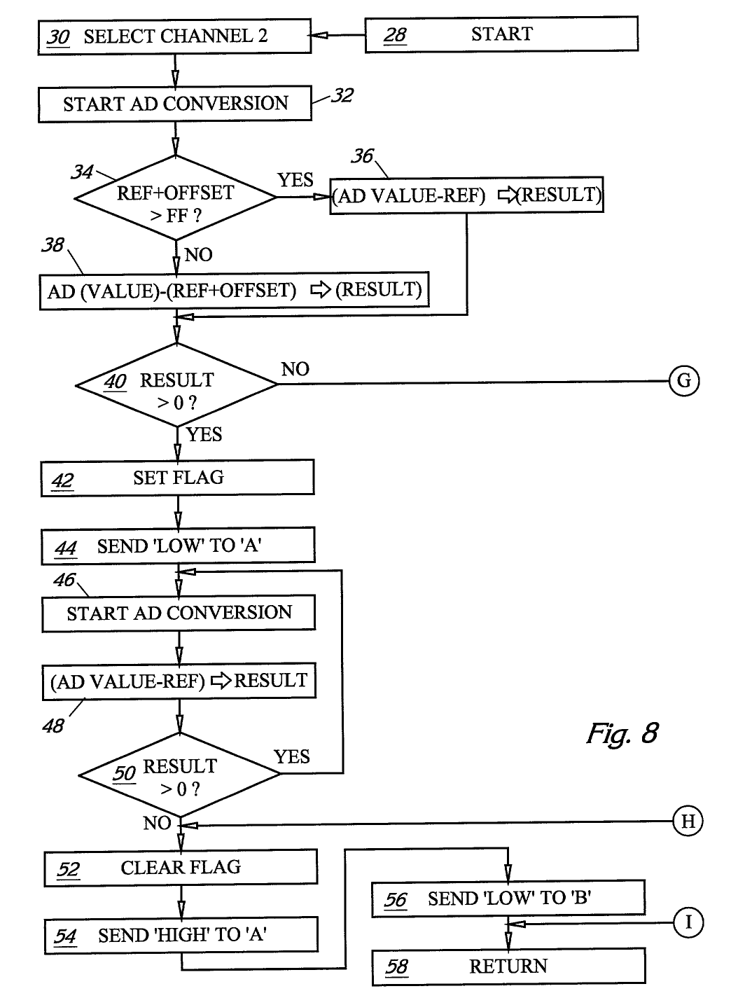

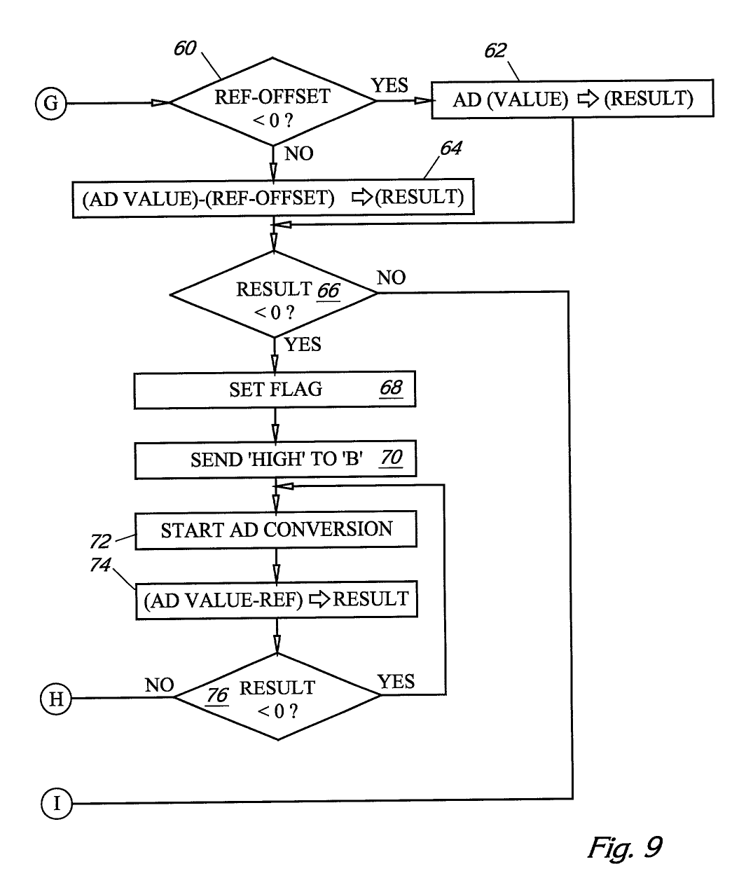

FIGS. 8 and 9, illustrate, in flowchart form, the unique process utilized by the present invention to mimic a traditional analog agc circuit, by digital means.

First, the microprocessor selects the proper channel for the A/D converter, via steps 28-32 and takes a sample of the detector voltage located at the amplifier U3 output. This voltage is proportional to the power of the output signal. This value is converted to a digital word and is stored in memory under “AD(VALUE)”.

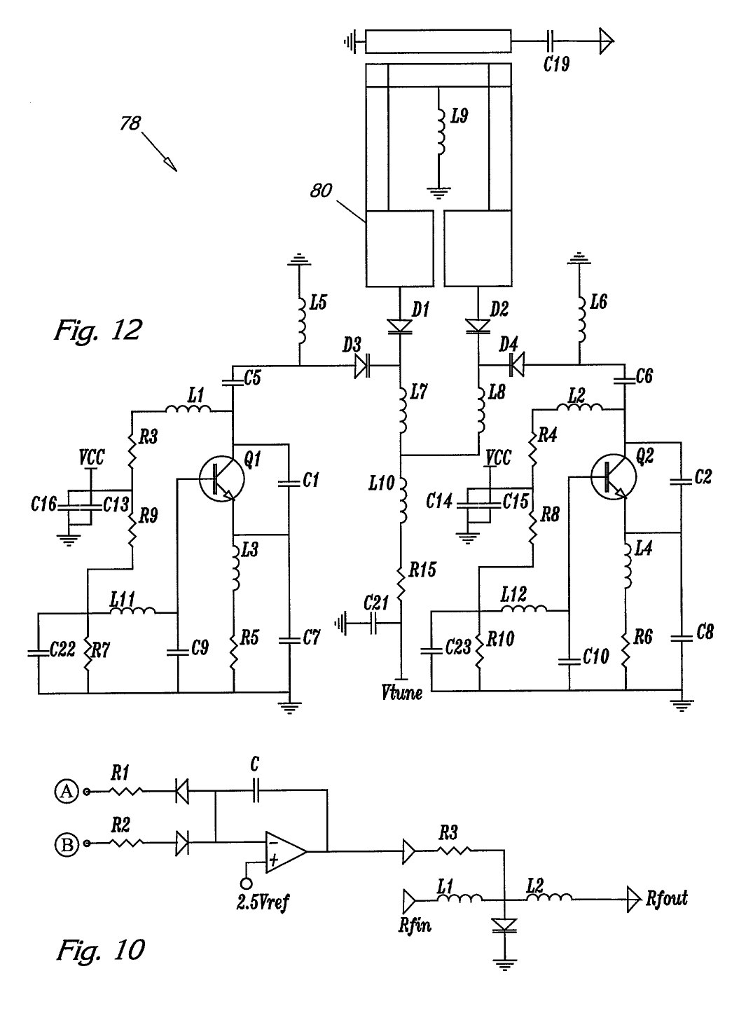

At this point, AD(VALUE) is compared with another value already stored in memory, (REF), and if AD(VALUE) is greater than REF, the processor inputs “low” for the I/O output referred to as “A”. This is accomplished via steps 34-44. Because “A” is the input for an analog integrator circuit (see FIG. 10), its output voltage begins to slowly increase, causing the pin diode connected to the integrator output to reduce its impedance, thereby increasing the total main circuit attenuation. The microprocessor continues to check the relationship of these two values.

When the values of AD(VALUE) and REF are equal, the processor changes “A” to a “high” reading and freezes the output voltage at that particular point, via steps 46-58. If REF is greater than AD(VALUE), output “B” then goes high, and the pin diode voltage starts to decrease, via steps 60-76. An “OFFSET” is introduced as an added value to “REF” in order to reduce circuit sensitivity.

Power Supply

The power supply of the present RF synthesizer is a switching power supply generating voltages according to the requirements for low noise, e.g. +5V, +12V, −12V, +3.5V, +9V and +28V. A switching regulator configuration is used, including active filters to reduce line noise to less than 30nVᵣₘₛ. The various voltages are then distributed throughout the module, for each of the various sub-modules, with each section monitored for current limit. Upon detecting a current exceeding a preset specification, the power supply will initiate a controlled shut down of the main module and record the fault. In addition, the power supply is shielded so as not to radiate magnetic or electromagnetic interference.

YIG-Replacement Oscillator

The present invention is designed to achieve wide band frequency coverage for high speed wireless communication systems. While traditional YIGs are RF carrier generation devices characterized by good phase noise, they tune slowly have high power requirements use rare earth materials and require critical dimensions for construction.

The key component of the present invention is an RF oscillator (“VCO”) designed to replace existing YIG-based oscillators. It is based upon a modified push-push VCO design yet contains additional circuitry to provide increased bandwidth coverage and tuning range and provide increased noise reduction.

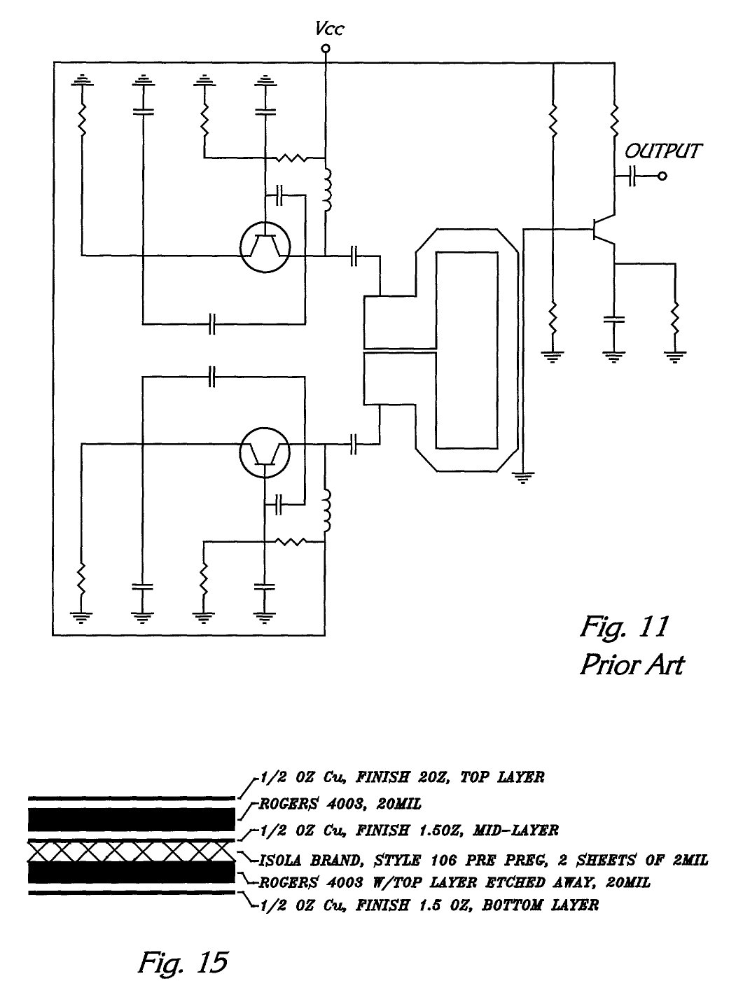

FIG. 11 illustrates a traditional “push-push” VCO commonly used in the art. The basic oscillator consists of a Colpitts circuit with a common base configuration. Two identical oscillator circuits are built from resonators having a resonant mode 180 degrees out of phase with each other. One part of the circuit oscillates at the fundamental resonant response frequency, dependent upon the stepped impedance of the hairpin resonator. The other part of the circuit oscillates at the same frequency, but 180 degrees out of phase.

A typical push-push VCO has a wide tuning band. The output is obtained by summing the fundamental frequency. Hence, the maximum oscillator power frequency is doubled and the achievable phase noise performance is potentially better than conventional topologies designed for the same frequency. If there are N identical oscillators and their output voltages are summed in phase, the total carrier power is multiplied by N². If the noise power increases by the same factor of N, the phase noise relative to the carrier decreases by a factor of N.

In theory, the output phase noise spectral density produced by two bilaterally coupled identical oscillators is 3 dB lower than a single oscillator. If the signal generated by two coupled oscillators in phase opposition are subtracted, the amplitude of the sinusoidal waveform generated by the push-push oscillator is doubled compared to the one generated by a single oscillator, and the output power is 6 dB higher.

This configuration, known in the art as a “push-push” vco, has, theoretically, a 9 dB improvement in phase noise as compared to a single ended vco. However, typical implementations rarely see better than a 3 dB improvement.

Phase noise depends strongly on the quality factor (Q) of the tank. The Q of spiral inductors is proportional to frequency only up to a certain point, beyond which it degrades due to losses induced by skin effect and bulk eddy currents. The Q of varactors is inversely proportional to frequency. For high-frequency operation, the nonlinear parasitic capacitance of active devices in the oscillator core tends to become a significant fraction of the total tank capacitance. Hence, the achievable phase noise performance of a vco degrades at higher frequencies. Thus, the output frequency of a VCO should be set to the point where the inductor Q is optimal and device parasitics must be kept a small fraction of the tank impedance. Frequency doublers may be used to obtain higher frequencies. However, these typically introduce distortion and have poor phase noise performance.

FIG. 12 illustrates the modified push-push VCO utilized in the present invention, shown generally as 78. VCO 78 is constructed such that there are two active devices driving opposite ends of a transmission line. The devices oscillate 180 degrees out of phase with each other. The transmission line has the properties of a resonant tank circuit and can be tuned via varactor diodes.

VCO 78 utilized in the preferred embodiment of the present invention is designed to obtain a 9 dB phase noise improvement by incorporating a resonator with a high loaded Q. The resonator 80 within VCO 78 is formed via a buried stripline hairpin structure, which maximizes loaded Q and additionally shields the resonator from outside EMI. Tests have shown that the improved push-push design yields phase noise improvement approaching the theoretical 9 dB.

VCO 78 tunes like a traditional voltage control oscillator, thereby providing high tuning speed and minimal power requirements. VCO 78 covers several hundreds of MHz, and is thereafter multiplied up to the mm-wave band.

VCOs are tuned using varactor diodes, which in combination with circuit inductance tune the vco over the desired frequency range. In VCO 78, the circuit that tunes the hairpin resonator is itself tuned by an additional circuit, providing increased bandwidth coverage.

Referring to FIG. 12, D1-D4 represent the varactor diodes which tune the hairpin resonator. In series with D1 and D2 are inductors L7 and L8. Typically these would be RF chokes or large resistor values to isolate the tuning circuit from the tuning line. However, if L7 and L8 are small inductance values, and an additional inductor L10 (an RF choke) is added for isolation, then the affect of L7 and L8 is to increase the tuning range by reducing the effective varactor capacitance as the frequency increases.

Bipolar transistors are typically biased with resistive divider networks which in themselves generates low frequency 1/f noise. In addition, the transistor also generates low frequency noise of a 1/f nature, which when combined with the resistive noise modulates the oscillator's carrier, degrading phase noise.

Inductors L11, L12, and capacitors C22 and C23, form a noise-reduction circuit for this type of noise. In operation, L11 acts as an RF choke for the oscillator's carrier but is of low resistance for audio and 1/f noise. C22 acts as a bypass cap, shunting the 1/f noise to ground, which improves the phase noise close to the carrier by approximately 2 dB.

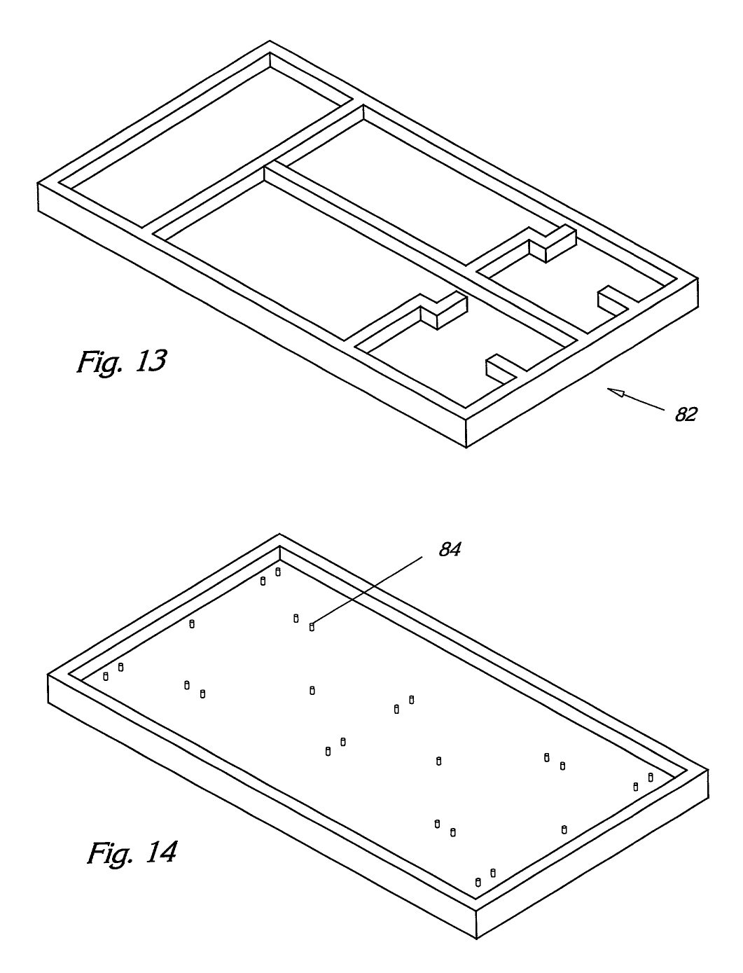

Resonator 80 of FIG. 12 is buried within a number of layers. Referring to FIG. 15, in the preferred embodiment of the present invention, a top layer of ½ oz. Copper is followed by a second layer of Rogers 4003, a woven glass cloth material impregnated with a ceramic loaded thermoset plastic resin to yield a thermally stable rigid laminate with electrical properties suitable at microwave frequencies. Following is the resonator, a ½ oz. Copper middle layer and a dielectric substrate, preferably an ISOLA style 106 prepreg. Another layer of Rogers 4003 with the top layer etched away resides directly underneath the substrate. The bottom layer is another ½ oz. Copper layer. The improved oscillator of the invention preferably has a finished board thickness of 47 mils.

Housing

FIGS. 13 and 14 show the housing of the present invention. The housing enclosing the RF synthesizer module 10 of the present invention is a uniquely designed modular enclosure which allows for the ferrying of voltages, controlling of signals and carriers, all without introducing unwanted spurious signals. The housing 82, is a machined aluminum block with various pockets removed for circuitry. The modular form of housing 82 functions to separate the various sub-modules of supermodule 10 and securing them within respective pockets. Sampling loop 20, Main Loop 10 and the mm-wave sections are each located in individual machined pockets. Each pocket contains feed-through capacitors 84 which provide connectivity to other parts of module 10. Feed-through capacitors 84 also provide isolation of the various sections, and in conjunction with a properly sealed housing lid, pocket to pocket isolation exceeds 70 dB. FIG. 14 illustrates the bottom of housing 82, showing the feed-through capacitors 84 exiting through the bottom of the housing. Further, by separating the individual functions of module (main loop, sampling loop etc.), upgrades to the module can be readily accomplished in a time and cost-effective manner by swapping out boards; the architecture and the housing remain the same.

Software

The software of the present invention is designed to monitor a variety of system parameters, and can be upgraded remotely via an i²c interface. Upon power up, the unit verifies that the input voltages are within normal readings, and then activates the various subsections of the module. Additional voltages generated by the power supply are constantly monitored and the module will initiate a controlled shutdown if any of the voltages are out of spec.

The software also controls the module's agc (described above), output power and bias current. Module temperature is also recorded and monitored over the product's lifetime. A key feature of the software is it's remote configuration capability. Given the proper control sequence, key parameters can be adjusted “on the fly”, providing extreme flexibility for adjusting output power, phase noise and switching speed.

The instant invention has been shown and described herein in what is considered to be the most practical and preferred embodiment for a dual conversion RF synthesizer utilizing an improved push-push vco design. It is recognized, however, that departures may be made therefrom within the scope of the invention and that obvious modifications will occur to a person skilled in the art.

What is claimed is:

1. A dual conversion radio frequency synthesizer having various submodules for producing a controlled RF output signal, said synthesizer comprising:
means for generating a first IF signal;
means for generating a second IF signal; and
means for controlling the power level of an RF output signal and maintaining said RF signal within an acceptable range wherein said RF output signal is a spurious free output signal comprised of harmonically related component signals.

2. The synthesizer of claim 1 wherein said power level controlling means comprises:
a mm-wave amplifier having a detector diode for amplifying and rectifying mm-wave signals and for providing a DC voltage proportional to the power of said RF output signal; and
a microcontroller coupled to said mm-wave amplifier, said microcontroller including means for detecting and measuring the value of said DC voltage and including means for variably adjusting said power level of said RF output signal.

3. The synthesizer of claim 1 further comprising a housing for separately enclosing said submodules, said housing comprised of a plurality of pockets, each pocket to retain one submodule thereby allowing one said submodule to be removed and replaced without the need to alter another said submodule, each said submodule communicating with one or more other said submodules via electrical connectors.

4. A dual conversion radio frequency synthesizer having various submodules for producing a controlled RF output signal, said synthesizer comprising:
means for generating an RF signal;
means for generating a fixed carrier signal;
means for coupling said RF signal with said fixed carrier signal to generate a first IF signal;
means for coupling said fixed carrier signal with said first IF signal to produce a second IF signal; and
means for controlling the power level of an RF output signal and maintaining said RF output signal within an acceptable range wherein said RF output signal is a spurious free output signal comprised of harmonically related component signals.

5. The synthesizer of claim 4 wherein said means for generating said fixed carrier signal is comprised of:
an amplifier driven by an external reference signal;
a sampling phase detector driven by said amplifier thereby generating harmonic signals of said external reference signal;
a VCO generating a signal driving a side of said sampling phase detector and coupling with said harmonic signals thereby producing an output voltage proportional to a phase differential between said VCO signal and said harmonic signals;
an active loop filter for phase locking and controlling said VCO signal;
means for determining if said VCO is generating an offset voltage and if so, to provide an opposite swing voltage driving said VCO in an opposite direction; and
means for doubling said VCO signal.

6. The synthesizer of claim 4 wherein said power controlling means comprises:
a mm-wave amplifier having a detector diode for amplifying and rectifying mm-wave signals and for providing a DC voltage proportional to the power of said resultant RF output signal; and
a microcontroller coupled to said mm-wave amplifier, said microcontroller including means for detecting and measuring the value of said DC voltage and including means for variably adjusting said RF output power.

7. A dual conversion radio frequency synthesizer having various submodules for producing a controlled RF output signal, said synthesizer comprising:
means for generating millimeter wave frequency signals;
means for multiplying said millimeter frequency signals by a factor of N;
means for generating a fixed carrier signal;
means for multiplying said fixed carrier signal by a factor of N;
means for coupling said multiplied millimeter frequency signal with said multiplied fixed carrier signal to generate a first IF signal;
means for coupling said fixed carrier signal with said first IF signal to produce a second IF signal;
means for phase locking said second IF signal to an external reference;
means for coupling said millimeter frequency signal with said multiplied millimeter frequency signal to produce a resultant frequency signal;
means for multiplying said resultant frequency signal by a factor of N to produce a spurious free RF output signal comprised of harmonically related component signals; and
means for controlling the power level of said RF output signal and maintaining said RF output signal within an acceptable range.

8. The synthesizer of claim 7 wherein N equals 2.

9. The synthesizer of claim 7 wherein said means for multiplying said millimeter frequency signals by a factor of N is a frequency doubler.

10. The synthesizer of claim 7 wherein said means for generating said fixed carrier signal is comprised of:
an amplifier driven by an external reference signal;
a sampling phase detector driven by said amplifier thereby generating harmonic signals of said external reference signal;
a VCO generating a signal driving a side of said sampling phase detector and coupling with said harmonic signals thereby producing an output voltage proportional to a phase differential between said VCO signal and said harmonic signals;
an active loop filter for phase locking and controlling said VCO signal;
means for determining if said VCO is generating an offset voltage and if so, to provide an opposite swing voltage driving said VCO in an opposite direction; and
means for doubling said VCO signal.

11. The synthesizer of claim 7 wherein said means for phase locking said second IF signal comprises an amplifier driving a dual modulus prescaler and fractional PLL chip.

12. The synthesizer of claim 7 further comprising a housing for separately enclosing said submodules, said housing comprised of a plurality of pockets, each pocket to retain one submodule thereby allowing one said submodule to be removed and replaced without the need to alter another said submodule, each said submodule communicating with one or more other said submodules via electrical connectors.

13. The synthesizer of claim 7 wherein said means for generating millimeter wave frequencies is a voltage control oscillator comprising:
a substrate;
high Q resonator means embedded within said substrate, said resonator comprised of a buried stripline hairpin structure;
an oscillator tuning circuit comprised of one or more varactor diodes electrically coupled to said resonator means, said circuit comprising amplifying means and means for tuning said oscillator over a desired frequency range;
a second circuit comprised of one or more inductors in series with said one or more varactor diodes, said second circuit electrically coupled to said oscillator tuning circuit for tuning said oscillator tuning circuit thereby reducing effective varactor capacitance as frequency increases; and
a noise reduction circuit for improving phase noise comprised of an amplifier biasing circuit including an RF choke and means for shunting 1/f noise to ground.

14. A voltage control oscillator comprising:
a substrate;
high Q resonator means embedded within said substrate;
an oscillator tuning circuit electrically coupled to said resonator means, said circuit comprising amplifying means and means for tuning said oscillator over a desired frequency range; and
a second circuit electrically coupled to said oscillator tuning circuit for tuning said oscillator tuning circuit thereby reducing effective varactor capacitance as frequency increases.

15. The voltage control oscillator of claim 14 wherein said tuning means comprises one or more varactor diodes.

16. The voltage control oscillator of claim 15 wherein said second circuit comprises one or more inductors in series with said one or more varactor diodes.

17. The voltage control oscillator of claim 16 further comprising a noise reduction circuit for improving phase noise.

18. The voltage control oscillator of claim 17 wherein said noise reduction circuit comprises an amplifier biasing circuit including an RF choke and means for shunting 1/f noise to ground.

19. The voltage control oscillator of claim 14 wherein said resonator is comprised of a buried stripline hairpin structure.

20. A method for producing a controlled RF output signal, comprising the steps of:
generating a first IF signal;
generating a second IF signal; and
controlling the power level of an RF output signal and maintaining said RF signal within an acceptable range wherein said RF output signal is a spurious free output signal comprised of harmonically related component signals.

21. The method claim 20 wherein the step of controlling the power level of an RF output signal includes providing a mm-wave amplifier having a detector diode for amplifying and rectifying mm-wave signals and for providing a DC voltage proportional to the power of said RF output signal, and providing a microcontroller coupled to said mm-wave amplifier for detecting and measuring the value of said DC voltage and variably adjusting said power level of said RF output signal.

22. The method of claim 20 further comprising the step of separately enclosing said submodules by providing housing having a plurality of pockets, each pocket to retain one submodule thereby allowing one said submodule to be removed and replaced without the need to alter another said submodule, each said submodule communicating with one or more other said submodules via electrical connectors.
